(19) United States
(12) Patent Application Publication
(10) Pub. No.: US 2015/0195925 A1
(43) Pub. Date: Jul. 9, 2015

(54) DISPLAY DEVICE

(71) Applicant: Funai Electric Co., Ltd., Osaka (JP)

(72) Inventors: Yasuyuki FUKUMOTO, Osaka (JP); Akihiro FUJIKAWA, Osaka (JP); Atsunori ZENSAI, Osaka (JP)

(21) Appl. No.: 14/589,029

(22) Filed: Jan. 5, 2015

(30) Foreign Application Priority Data
Jan. 8, 2014 (JP) 2014-001771

(51) Int. Cl. H05K 5/00; H05K 5/02; H05K 7/14

(52) U.S. Cl. CPC H05K 5/0017; H05K 7/1427; H05K 5/0217

(57) ABSTRACT

A display device includes a display module configured to display images, a front housing, and a rear housing configured to hold and cover the display module between the front housing and configured to be separated into a first separate member and a second separate member. The rear housing includes a wall panel extending inward toward the display module from an area at or near one of the end portions of the first separate member that is closer to the second separate member.

### BACKGROUND OF THE INVENTION

1. Field of the Invention

The present invention relates to a display device, and more particularly, to a display device including a separable rear housing.

2. Description of the Related Art

A conventional display device including a separable rear housing is known (for example, see Japanese Patent Application Laid-Open No. 2009-229998).

In Japanese Patent Application Laid-Open No. 2009-229998, a display device including a display unit and a rear housing that is arranged in the back of the display unit and can be separated into a pair of back covers is disclosed. The separated pair of back covers of the display device discussed in Japanese Patent Application Laid-Open No. 2009-229998 have a bilaterally symmetric shape about a vertical line passing through a center point of the display unit.

The display device discussed in Japanese Patent Application Laid-Open No. 2009-229998 however has a disadvantage that since the rear housing is separated into the pair of back covers, portions of the rear housing near the separation are easily bent and deformed by an external force.

### SUMMARY OF THE INVENTION

Preferred embodiments of the present invention provide a display device configured to significantly reduce or prevent bending and deformation of a separable rear housing.

One aspect of various preferred embodiments of the present invention is a display device including a display module configured to display images, a front housing, and a rear housing configured to hold and cover the display module between the front housing and to be separated into at least a first separate member and a second separate member. The rear housing includes a wall panel extending inward toward the display module from an area at or near at least one of the end portions of the first separate member close to the second separate member and one of the end portions of the second separate member that is closer to the first separate member.

As described above, since the display device according to the above aspect of various preferred embodiments of the present invention has the rear housing including the wall panel extending inward toward the display module from an area at or near at least one of the end portions of the first separate member that is closer to the second separate member and one of the end portions of the second separate member close to the first separate member, the wall panel significantly reduces or prevents deterioration in rigidity of the separable rear housing, thus significantly reducing or preventing bending and deformation of the rear housing. Further, the wall panel of the rear housing provides a partition between the first separate member and the second separate member and thus reduces the light that has entered the rear housing through an opening in the back side of the display module leaking from one of the first separate member and the second separate member to the other member and eventually leaking outside.

In the display device according to the above aspect, the wall panel of the rear housing preferably extends along a separation line determined by one of the end portions of the first separate member that is closer to the second separate member and one of the end portions of the second separate member that is closer to the first separate member. Because the wall panel, extending along the separation line toward the display module, is provided at the portion near the separation line where the deterioration in rigidity is likely to occur, the structure efficiently reduces or prevents the deterioration in rigidity of the rear housing, thus efficiently reducing or preventing bending and deformation of the rear housing. Further, the wall panel extending along the separation line provides a partition with a larger area to improve the effect of reducing the light leaking outside.

In the display device according to the above aspect of various preferred embodiments of the present invention, the first separate member of the rear housing preferably includes an internally overlapping portion that overlaps with an inner side of one of the end portions of the second separate member that is closer to the first separate member. The wall panel of the rear housing extends inward toward the display module from the internally overlapping portion of the first separate member. With this structure, the internally overlapping portion of the first separate member provided with the wall panel supports the second separate member from the inner side, thus significantly reducing or preventing the inward bending and deformation of the second separate member caused by an external force. Accordingly, a simple structure requiring no wall panel in the second separate member significantly reduces or prevents the deterioration in rigidity of the rear housing.

In this case, the first separate member of the rear housing preferably includes a stepped portion that recesses inward so that the internally overlapping portion overlaps with the inner side of one of the end portions of the second separate member that is closer to the first separate member. The rear housing is configured such that an outer surface of the first separate member and an outer surface of the second separate member are co-planar or approximately co-planar with each other when the internally overlapping portion of the first separate member and one of end portions close to the first separate member of the second separate member overlap with each other. This structure provided with the inwardly recessing stepped portion in the first separate member reduces the possibility of the outer surfaces having different projection heights (having a step) at the boundary between the first separate member and the second separate member when the first separate member and the second separate member are assembled to form the rear housing (when the internally overlapping portion and one of the end portions of the second separate member that is closer to the first separate member are overlapping).

In the display device including the first separate member of the rear housing including the internally overlapping portion and the stepped portion, the rear housing is preferably configured such that a side end surface of one of the end portions of the second separate member that is closer to the first separate member and a side surface of the stepped portion facing the side end surface are separated by a predetermined distance when the internally overlapping portion of the first separate member and one of the end portions of the second separate member that is closer to the first separate member overlap with each other. Since the side end surface of one of the end portions of the second separate member that is closer to the first separate member and the side surface of the stepped portion facing the side end surface are separated by the predetermined distance, this structure allows a larger dimensional tolerance for the first separate member and the second separate member, which reduces the rate of producing defective mold products. As a result, the manufacturing yield is greatly improved and thus productivity (mass productivity) is greatly improved.

Preferably, in the display device according to the above aspect of various preferred embodiments of the present invention, the wall panel of the rear housing is located in an area at or near one of the end portions of the first separate member that is closer to the second separate member and includes a first engagement portion projecting toward the second separate member, and the second separate member of the rear housing includes a second engagement portion configured to engage with the first engagement portion to prevent the second separate member from rising against the first separate member. By the first engagement portion of the first separate member and the second engagement portion of the second separate member engaging with each other, the structure prevents the second separate member from rising against the first separate member. Accordingly, this reduces the possibility of the outer surfaces having different projection heights (having a step) at the boundary between the first separate member and the second separate member when the first separate member and the second separate member are assembled to form the rear housing.

Preferably, in the display device according to the above aspect of various preferred embodiments of the present invention, the display module includes a display panel and a rear frame configured to support the display panel, and the wall panel of the rear housing extends to an area at or near the rear frame. For example, when an external force is applied inward on the rear housing when the display device is hanged on a wall, this structure allows the wall panel extending to the area at or near the rear frame to make contact with the rear frame, thus significantly reducing or preventing bending and deformation of the rear housing. Moreover, the wall panel extending to the area at or near of the rear frame provides a partition with a larger area to further reduce the light that has entered the rear housing through an opening of the rear frame in the back side of the display module leaking from one of the first separate member and the second separate member to the other member and eventually leaking outside.

Preferably, in this case, the display unit further includes a circuit board arranged in the inner side of either of the first separate member and the second separate member but not in the inner side of the other member. One of the first separate member and the second separate member that does not include the circuit board preferably is made of a material having lower fire-resistance than a material of the other member in which the inner side the circuit board is arranged. While the material of the other member in which inner side the circuit board generating heat is arranged preferably is made of a fire-resistance material, the material of the other member in which inner side no circuit board generating heat is arranged can be made of a material having lower fire-resistance than the material of the other member, so that the choice of materials of the first separate member and the second separate member constituting the rear housing is broadened.

Preferably, in the display device according to the above aspect of various preferred embodiments of the present invention, at least one of the first separate member and the second separate member of the rear housing is provided with a power cord holder configured to hold a power cord in the area at or near the separation line determined by one of the end portions of the first separate member that is located closer to the second separate member and one of end portions close to the first separate member of the second separate member. The first separate member and the second separate member are configured to hold the power cord in the power cord holder when assembled to form the rear housing. With this structure, using the rear housing which is configured to be separated into the first separate member and the second separate member, the first separate member and the second separate member hold the power cord in the power cord holder when the rear housing is configured with the first separate member and the second separate member. Since no power cord holder to hold the power cord is required to be provided in a member other than the rear housing, the power cord is arranged (held) with a simple structure using the separable rear housing.

As described above, according to various aspects of various preferred embodiments of the present invention, a display device that significantly reduces or prevents bending and deformation of the separable rear housing is provided.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a perspective view illustrating an overall configuration of a television device according to a first preferred embodiment of the present invention.

FIG. 2 is a rear view of the television device according to the first preferred embodiment of the present invention.

FIG. 3 is an exploded perspective view of the television device according to the first preferred embodiment of the present invention viewed from the front side.

FIG. 4 is an exploded perspective view of the television device according to the first preferred embodiment of the present invention viewed from the rear side.

FIG. 5 is a perspective view of a rear housing of the television device according to the first preferred embodiment of the present invention.

FIG. 6 is a schematic sectional view taken along the line 500-500 in FIG. 2.

FIG. 7 is a schematic sectional view taken along the line 600-600 in FIG. 2.

FIG. 8 is a schematic sectional view taken along the line 700-700 in FIG. 2.

FIG. 9 is an enlarged perspective view of a power cord arranging portion of the television device according to the first preferred embodiment of the present invention.

FIG. 10 is a rear view of the television device according to a second preferred embodiment of the present invention.

FIG. 11 is a rear view of the television device according to a third preferred embodiment of the present invention.

FIG. 12 is a schematic sectional view taken along the line 800-800 in FIG. 11.

### DETAILED DESCRIPTION OF THE PREFERRED EMBODIMENTS

Preferred embodiments of the present invention will be described referring to the drawings.

### First Preferred Embodiment

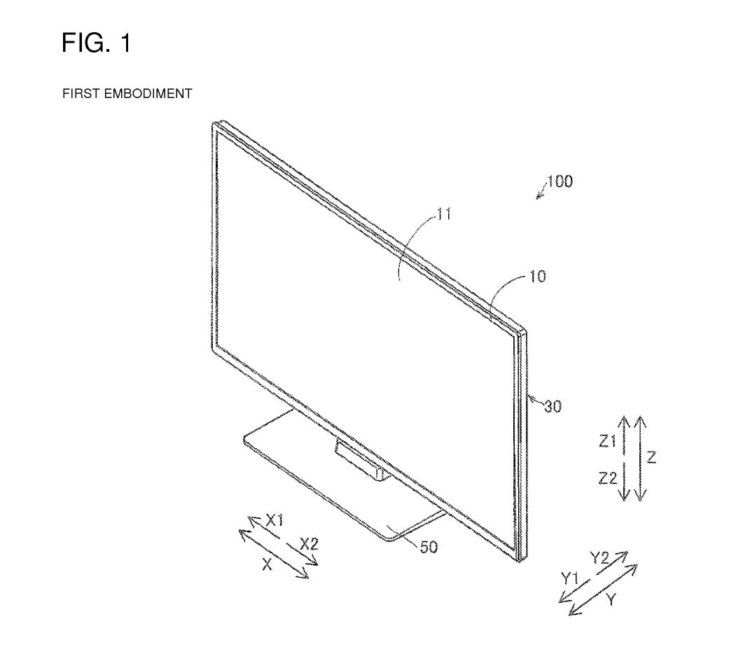

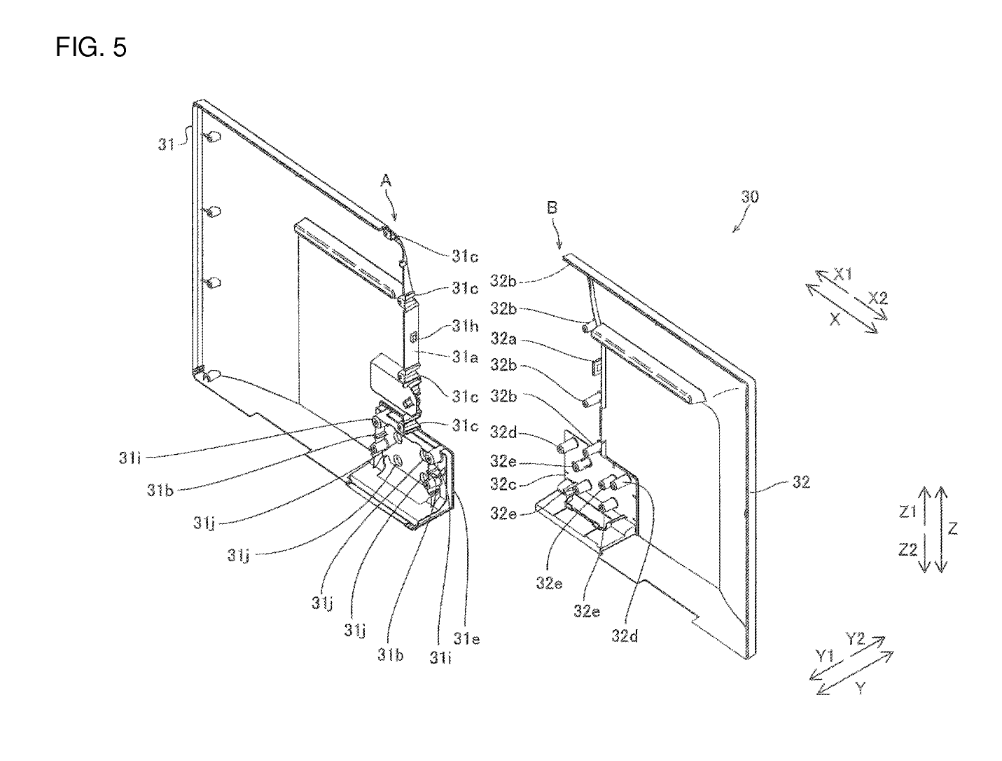

Referring to FIGS. 1 to 9, a structure of a television device 100 according to a first preferred embodiment of the present invention will be described. The television device 100 is an example of a “display device” according to the first preferred embodiment of the present invention.

As illustrated in FIGS. 1 to 4, the television device 100 according to the first preferred embodiment of the present invention includes a display module 10 including a display panel 11 configured to display images and a rear frame 12 configured to support the display panel 11, a resin front housing 20 preferably has a rectangular or substantially rectangular frame shape in a front view (when viewed from the Y2 direction), and a resin rear housing 30 separable into a first separate member 31 and a second separate member 32.

The television device 100 further includes a circuit board 40 including a signal processing board 41 arranged in the inner side (the side in the Y1 direction) of the first separate member 31 and a power source board 42 arranged in the inner side of the second separate member 32, a base 50 configured to support a device body including the display module 10, the front housing 20, and the rear housing 30, and a base attachment member 60 configured to attach the base 50. The signal processing board 41 and the power source board 42 are examples of a “circuit board” of a preferred embodiment of the present invention.

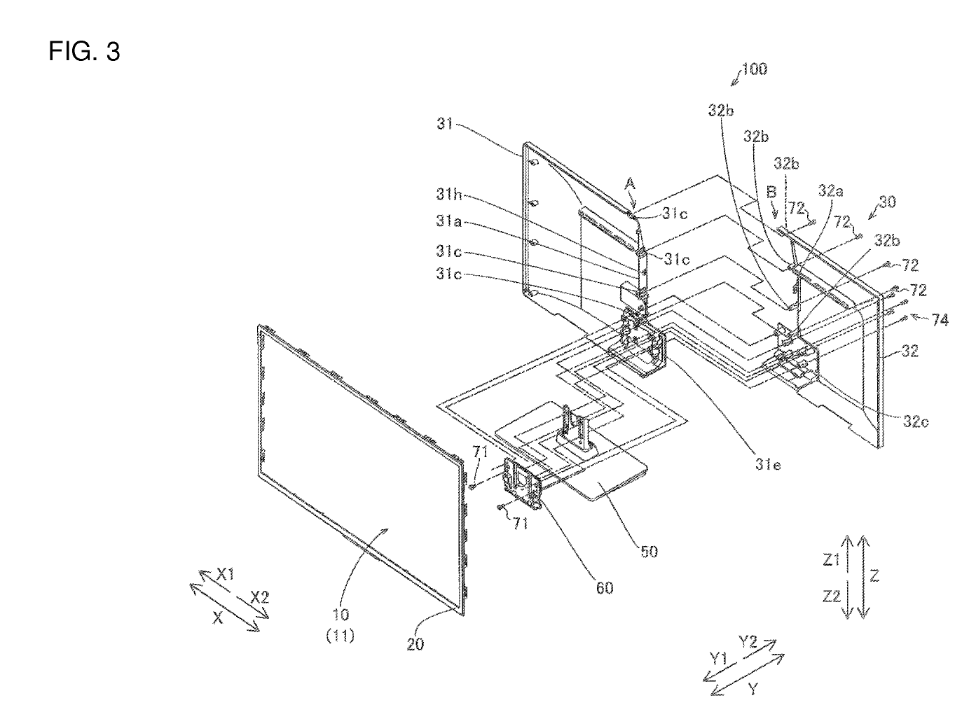

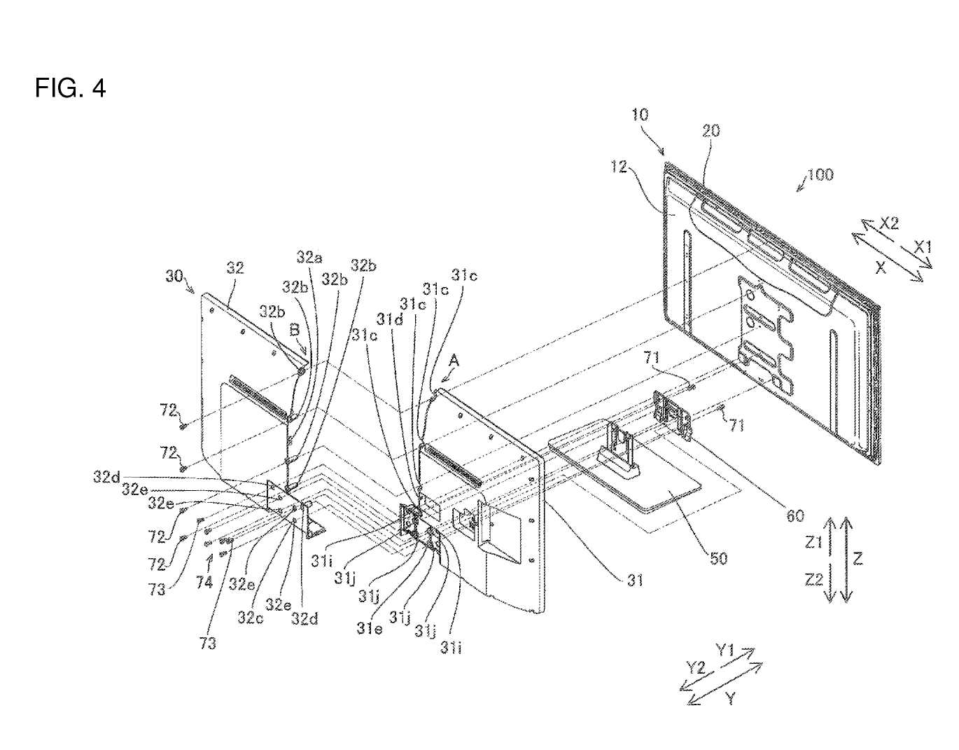

Referring to FIGS. 3 and 4, a manner in which the components of the television device 100 constitute the television device 100 will be described.

As illustrated in FIG. 3, the television device 100 is configured such that the base attachment member 60 is secured to the first separate member 31 preferably with a screw member 71, for example.

As illustrated in FIGS. 3 and 4, the television device 100 is configured such that the first separate member 31 and the second separate member 32 are attached to the rear frame 12 of the display module 10 with a screw member 72, and such that the first separate member 31, the second separate member 32, and the base attachment member 60 are attached to the rear frame 12 with a screw member 73.

Further, the television device 100 is configured such that the base 50 is inserted between the first separate member and the base attachment member 60 which is secured to the first separate member 31. The television device 100 is configured such that, with the base 50 disposed between the first separate member 31 and the base attachment member 60, the screw member 74 penetrates the second separate member 32 and the first separate member 31 in this order to attach the base 50 to the base attachment member 60.

Now referring to FIGS. 1 to 9, the configuration of each of the components constituting the main portions of the television device 100 will be described in order.

As illustrated in FIGS. 1, 3, and 4, the display module 10 preferably further includes, between the display panel using liquid crystals (liquid crystal panel) 11 and the metal rear frame 12, an optical member (not shown) configured to emit light to produce images. The display module 10 is thus configured to display images on the display panel 11 according to video signals.

The front housing 20 is configured to be attached to the rear frame 12 with a screw member (not shown), for example. In FIGS. 3 and 4, the front housing 20 is attached to the display module 10.

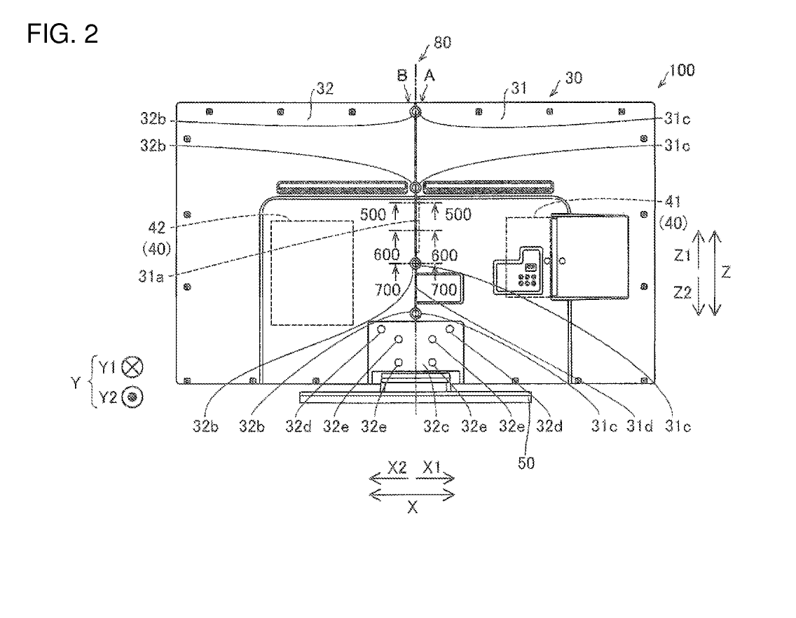

In the first preferred embodiment as illustrated in FIGS. 2 to 4, the rear housing 30 is configured to hold and cover the display module 10 between the front housing 20. The rear housing 30 is further configured to have a separation line defined by the first separate member 31 and the second separate member 32. Specifically, the rear housing 30 is configured to have the separation line 80 determined by an end portion A, which is one of the end portions of the first separate member that is closer to the second separate member 32 (the side in the X2 direction), and an end portion B, which is one of the end portions of the second separate member that is closer to the first separate member 31 (the side in the X1 direction).

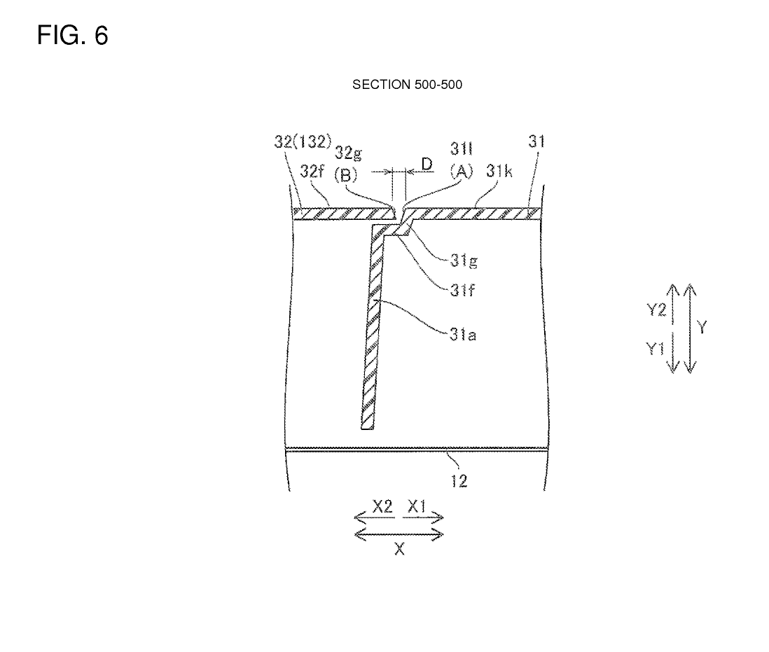

Further, in the first preferred embodiment as illustrated in FIGS. 2 to 6, a wall panel 31a extending inward (in the Y1 direction), a plurality of (e.g., two) bosses 31b each including a threaded hole configured to engage with the screw member 71, a plurality of (e.g., four) bosses 31c each including a penetration hole configured to receive the screw member 72 therein, a power cord holder 31d configured to hold a power cord 90 which will be described later, and a base attaching portion 31e configured to attach the base 50 are provided in the first separate member 31 of the rear housing 30. As illustrated in FIG. 6, an internally overlapping portion 31f configured to overlap with the inner side (the side in the Y1 direction) of the end portion B, that is, one of the end portions of the second separate member 32 that is located closer to the first separate member 31 (the side in the X1 direction) and a stepped portion 31g that recesses inward so that the internally overlapping portion 31f overlaps with the inner side of the end portion B are provided in the first separate member 31 of the rear housing 30.

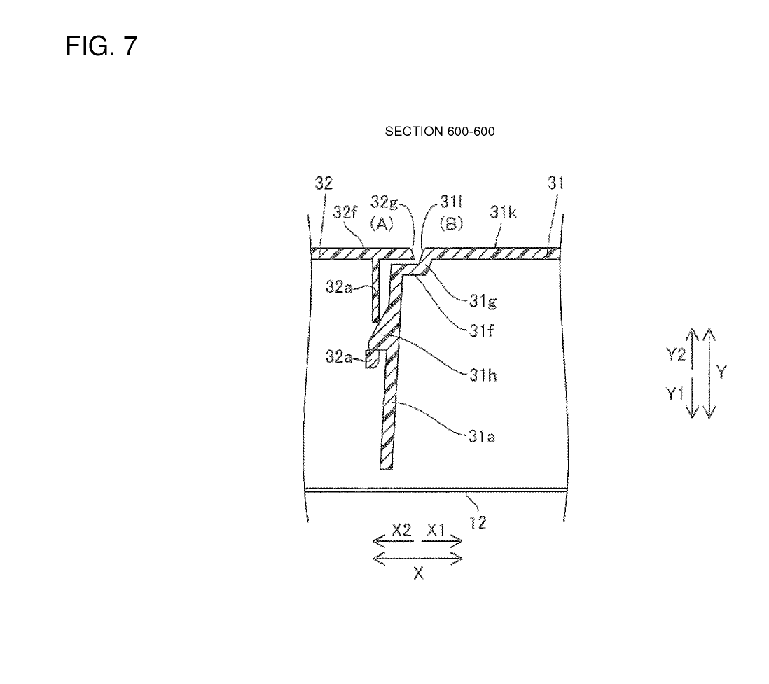

Further, as illustrated in FIG. 7, a first engagement portion 31h that projects toward the second separate member 32 (toward the X2 direction) and engages with a second engagement portion 32a of the second separate member 32, which will be described later, is provided on the wall panel 31a of the first separate member 31.

The base attaching portion 31e of the first separate member 31 is provided with a plurality of (e.g., two) bosses 31i each including a penetration hole configured to insert the screw member 73 therein and a plurality of (e.g., four) penetration holes 31j configured to receive the screw member 74 therein. The base attaching portion 31e extends (stretches out) toward the second separate member 32 (toward the X2 direction) farther than the separation line 80 (see FIG. 2). That is, the base 50 is configured to be attached to the base attaching portion 31e of the first separate member 31 to be attached with the base 50 without separating the portion.

Further, in the first preferred embodiment as illustrated in FIGS. 2 and 3, the wall panel 31a of the first separate member 31 extends from the area at or near the end portion A, that is, one of the end portions of the first separate member 31 toward the inner side (toward the Y1 direction) that is closer to the second separate member 32 (the side in the X2 direction) and also along the separation line 80. The wall panel 31a of the first separate member 31 is located close to the middle portion of the end portion A, that is, one of the end portions of the first separate member 31 that is closer to the second separate member 32. Specifically, the wall panel 31a of the first separate member 31 is located in the middle portion along the separation line 80 of the television device 100 between the two bosses 31c, that is, the second and third highest bosses 31c from the top (along the Z1 direction). As illustrated in FIG. 6, the wall panel 31a of the first separate member 31 extends from the internally overlapping portion 31f toward the inner side (toward the Y1 direction) to the area at or near the rear frame 12.

The wall panel 31a of the first separate member 31 preferably is integrally formed with the first separate member 31 so as to define a single unitary member. Specifically, the wall panel 31a of the first separate member 31, the stepped portion 31g, and the internally overlapping portion 31f preferably are integrally formed with the first separate member 31 so as to define a single unitary member. That is, the stepped portion 31g extends inward (in the Y1 direction) from the end portion A of the first separate member 31 to define a step, the internally overlapping portion 31f extends from the stepped portion 31g toward the second separate member (toward the X2 direction), and the wall panel 31a of the first separate member 31 extends from the area at or near the end portion A of the first separate member 31 extends toward the inner side (toward the Y1 direction) to reach the area at or near the rear frame 12.

As illustrated in FIG. 6, the rear housing 30 of the first preferred embodiment is configured such that the internally overlapping portion 31f of the first separate member overlaps with the end portion B, that is, one of the end portions of the second separate member 32 when viewed from the rear side (viewed along the Y1 direction) that is located closer to the first separate member 31 (the side in the X1 direction). The rear housing 30 is further configured such that an outer surface 31k of the first separate member 31 and an outer surface 32f of the second separate member 32 are co-planar or approximately co-planar with each other when the internally overlapping portion 31f and the end portion B overlap with each other.

The rear housing 30 is further configured such that a side end surface 32g of the end portion B and a side surface 31l of the stepped portion 31g facing the side end surface 32g are separated by a distance D when the internally overlapping portion 31f and the end portion B, that is, one of the end portions of the second separate member 32 that is closer to the first separate member 31, overlap with each other.

As illustrated in FIGS. 2 to 6, a second engagement portion 32a including a penetration hole that engages with the first engagement portion 31h, a plurality of (e.g., four) bosses 32b each including a penetration hole through which the screw member 72 is inserted, and a base attaching portion 32c configured to attach the base 50 are provided in the second separate member 32 of the rear housing 30. A plurality of (e.g., two) bosses 32d each including a penetration hole through which the screw member 73 is inserted and a plurality of (e.g., four) boss 32e each including a penetration hole through which the screw member 74 is inserted are provided in the base attaching portion 32c of the second separate member 32.

The base attaching portion 32c of the second separate member 32 extends (stretches out) to the first separate member (toward the X1 direction) farther than the separation line 80. As in a same manner as the base attaching portion 31e of the first separate member 31, the base 50 preferably is attached to the base attaching portion 32c of the second separate member 32 to be attached with the base 50 without separating the portion. The base attaching portion 32c of the second separate member 32 is configured to overlap with the base attaching portion 31e of the first separate member 31 when viewed from the rear side. Even when the rear housing 30 is separated into the first separate member 31 and the second separate member 32, the base attaching portions 31e and 32c are not separated since the first separate member 31 and the second separate member 32 are integrally provided in the first separate member 31 and the second separate member 32, respectively, to attach the base 50 thereto. This further reduces or prevents the reduction in strength at the portion where the base 50 is attached (the base attaching portions 31e and 32c).

As illustrated in FIG. 7, the second engagement portion 32a of the second separate member 32 is configured to engage with the first engagement portion 31h when the first separate member 31 and the second separate member 32 are assembled to form the rear housing 30 (when the internally overlapping portion 31f and the end portion B, that is, one of the end portions of the second separate member 32 that is closer to the first separate member 31 (the side in the X1 direction) overlap each other). The second engagement portion 32a of the second separate member 32 is configured to engage with the first engagement portion 31h, thus preventing the second separate member 32 from rising against the first separate member 31. Specifically, the second engagement portion 32a is configured such that the bottom surface of the penetration hole of the second engagement portion 32a contacts (engages) with the bottom surface of the first engagement portion 31h, thus preventing the rising (movement toward the Y2 direction) of the second separate member 32 against the first separate member 31.

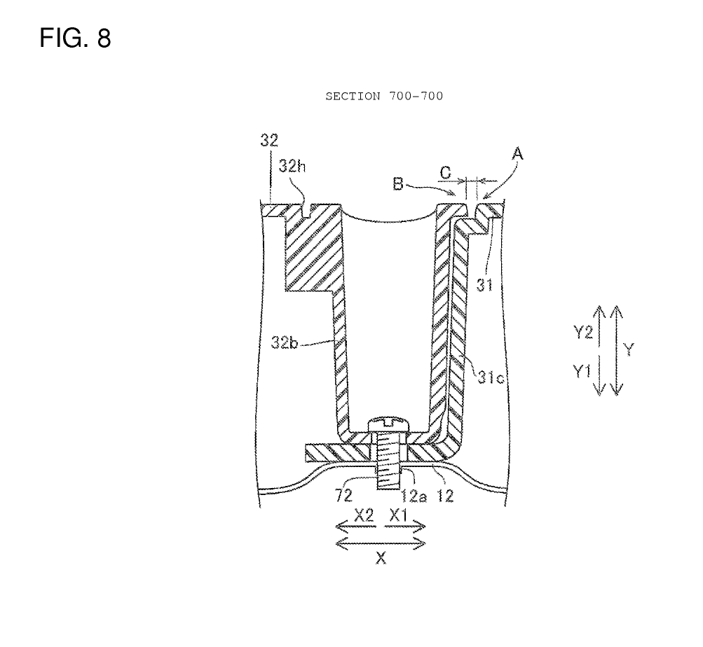

As illustrated in FIG. 8, the rear housing 30 of the first preferred embodiment is configured such that when the first separate member 31 and the second separate member 32 are assembled to form the rear housing 30, the boss 32b of the second separate member 32 and the boss 31c of the first separate member 31, both of which protrude inward (in the Y1 direction), are fitted together. The boss 31c preferably has an L-shape cross section and the boss 32b preferably has a U-shape cross section, for example. The boss 32b is arranged to be supported by the boss 31c from the inner side (the side in the Y1 direction). The rear housing 30 is configured to be attached to the rear frame 12 preferably by the screw member 72 securing the boss 32b and the boss 31c together and engaging with the threaded hole 12a of the rear frame 12, for example. In this manner, reduction in strength at the fastening portion (at the boss 32b and the boss 31c) caused by the screw member 72 is reliably prevented.

The rear housing 30 is configured to have a gap C between the boss 32b of the second separate member 32 and the boss 31c of the first separate member 31 when the first separate member 31 and the second separate member 32 are assembled to form the rear housing 30 so as to absorb dimensional tolerances. A groove 32h having a same or substantially the same width as the gap C is provided in the boss 32b of the second separate member 32 to provide an external appearance symmetrical to the gap C.

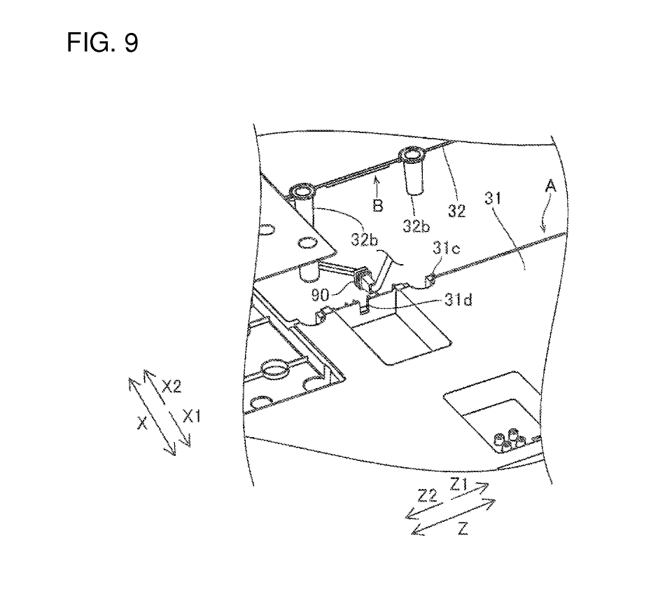

As illustrated in FIG. 9, the rear housing 30 is configured such that the power cord holder 31d of the first separate member 31 holds the power cord 90 when the first separate member 31 and the second separate member 32 are assembled to form the rear housing 30. Specifically, the rear housing 30 is configured such that, with the power cord 90 held in the notch-shaped power cord holder 31d, the power cord holder 31d and the end portion B, that is, one of the end portions of the second separate member 32 that is closer to the first separate member 31 (the side in the X1 direction), hold the power cord 90 when the first separate member 31 and the second separate member 32 are assembled to form the rear housing 30. FIG. 9 illustrates the first separate member 31 separated from the second separate member 32 for the ease of understanding.

The first preferred embodiment provides an effect as will be described below.

As described above, the first preferred embodiment is provided with the rear housing 30 including the wall panel 31a extending inward (in the Y1 direction) from the area at or near the end portion A, that is, one of the end portions of the first separate member 31 that is closer to the second separate member (the side in the X2 direction), toward the display module 10 to significantly reduce or prevent the deterioration in rigidity of the separable rear housing 30 by the wall panel 31a, so that bending and deformation of the rear housing 30 are significantly reduced or prevented. The wall panel 31a of the rear housing 30 provides a partition between the first separate member 31 (the side in the X1 direction) and the second separate member 32 (the side in the X2 direction) and thus significantly reduces the light that has entered the rear housing 30 (the side in the Y2 direction) through an opening (not shown) in the back side (the side in the Y2 direction) of the display module 10 leaking from one of the first separate member 31 and the second separate member 32 to the other member and eventually leaking outside by the wall panel 31a. Since the wall panel 31a extends inward from the area at or near the end portion A instead of extending outward (toward the Y2 direction), an increase in size of the television device 100 is prevented.

In the first preferred embodiment as described above, the wall panel 31a of the rear housing 30 is configured to extend along the separation line 80 determined by the end portion A, that is, one of end portions close to the second separate member 32 of the first separate member 31, and the end portion B, that is, one of end portions close to the first separate member 31 of the second separate member 32. Thus, at the area at or near the separation line 80 where rigidity is likely to decrease, the wall panel 31a is configured to extend along the separation line 80 and toward the display module 10, efficiently reducing or preventing the deterioration in rigidity of the rear housing 30 and thus efficiently reducing or preventing bending and deformation of the rear housing 30. With the wall panel 31a extending along the separation line 80, the wall panel 31a provides a partition with a larger area to improve the effect of reducing the light leaking outside.

As described above, the first preferred embodiment is configured such that the internally overlapping portion 31f that overlaps with the inner side of the end portion B, that is, one of the end portions of the second separate member 32 that is closer to the first separate member 31, is provided in the first separate member 31 of the rear housing 30. The wall panel 31a of the rear housing 30 extends inward toward the display module 10 from the internally overlapping portion 31f of the first separate member 31. This structure allows the internally overlapping portion 31f of the first separate member 31 provided with the wall panel 31a to support the second separate member 32 from the inner side, such that the internally overlapping portion 31f of the first separate member 31 significantly reduces or prevents the inward bending and deformation of the second separate member 32 caused by an external force, without providing the second separate member 32 with the wall panel 31a. Accordingly, a simple structure requiring no wall panel 31a in the second separate member 32 significantly reduces or prevents the deterioration in rigidity of the rear housing 30.

As described above, the first preferred embodiment is configured such that a stepped portion 31g that recesses inward so as the internally overlapping portion 31f to overlap with the inner side of the end portion B, that is, one of the end portions of the second separate member 32 that is closer to the first separate member 31, is provided in the first separate member 31 of the rear housing 30. The rear housing 30 is configured such that the outer surface 31k of the first separate member 31 and an outer surface 32f of the second separate member 32 are co-planar or approximately co-planar with each other when the internally overlapping portion 31f of the first separate member 31 and the end portion B overlap with each other. This structure provided with the inwardly recessing stepped portion 31g in the first separate member 31 reduces the possibility of the outer surfaces having different projection heights (having a step) at the boundary between the first separate member 31 and the second separate member 32 when the first separate member 31 and the second separate member 32 are assembled to form the rear housing 30 (when the internally overlapping portion 31f and the end portion B are overlapping).

In the first preferred embodiment as described above, the rear housing 30 is configured such that the side end surface 32g of the end portion B, that is, one of the end portions of the second separate member 32 that is closer to the first separate member 31, and the side surface 31l of the stepped portion 31g facing the side end surface 32g are separated by the distance D when the internally overlapping portion 31f of the first separate member 31 and the end portion B, that is, one of end portions close to the first separate member 31 of the second separate member 32, overlap with each other. Since the side end surface 32g of the end portion B, that is, one of the end portions of the second separate member 32 that is closer to the first separate member 31, and the side surface 31l of the stepped portion 31g facing the side end surface 32g are separated by the predetermined distance D, this structure allows a larger dimensional tolerance for the first separate member 31 and the second separate member 32, thus reducing the possibility of producing defective mold products. As a result, a manufacturing yield is greatly improved and thus productivity (mass productivity) is greatly improved.

In the first preferred embodiment as described above, the wall panel 31a is provided in an area at or near the end portion A, that is, one of the end portions of the first separate member 31 that is closer to the second separate member 32, and the first engagement portion 31h projecting toward the second separate member 32 is provided on the wall panel 31a of the rear housing 30. A second engagement portion 32a configured to engage with the first engagement portion 31h to prevent the second separate member 32 from rising against the first separate member 31 is provided in the second separate member 32 of the rear housing 30. This structure allows the first engagement portion 31h of the first separate member 31 and the second engagement portion 32a of the second separate member 32 to engage with each other, thus preventing the second separate member 32 from rising (moving toward the Y2 direction) against the first separate member 31. Accordingly, the possibility of the outer surfaces having different projection heights (having a step) at the boundary between the first separate member 31 and the second separate member 32 when the first separate member 31 and the second separate member 32 are assembled to form the rear housing 30 is significantly reduced. To prevent the rising of the second separate member 32 against the first separate member 31, it is very effective to provide the second engagement portion 32a that engages with the first engagement portion 31h particularly between the boss 32b and the boss 31c where the pressing force produced by attaching the screw member 72 tends to cause the rising.

In the first preferred embodiment as described above, the display module 10 includes the display panel 11 and a rear frame 12 configured to support the display panel 11. The wall panel 31a of the rear housing 30 extends to the area at or near the rear frame 12. For example, when an external force is applied to the rear housing 30 toward the inner side when the television device 100 is hanged on a wall, this structure allows the wall panel 31a extending to the area at or near the rear frame 12 to make contact with the rear frame 12, thus significantly reducing or preventing bending and deformation of the rear housing 30. Moreover, the wall panel 31a configured to extend to the area at or near of the rear frame 12 provides a partition with a larger area by the wall panel 31a to further reduce the light that has entered the rear housing 30 through the opening (not shown) of the rear frame 12 in the back side (the side in the Y2 direction) of the display module 10 leaking from one of the first separate member 31 and the second separate member 32 to the other member and eventually leaking outside by the wall panel 31a.

In the first preferred embodiment as described above, the first separate member 31 of the rear housing 30 is preferably provided with the power cord holder 31d configured to hold the power cord 90 in the area at or near the separation line 80. The television device 100 is configured to hold the power cord 90 in the power cord holder 31d when the first separate member 31 and the second separate member 32 are assembled to form the rear housing 30. With this structure, using the rear housing 30 which is capable of being separated into the first separate member 31 and the second separate member 32, the first separate member 31 and the second separate member 32 assembled to form the rear housing 30 hold the power cord 90 by the first separate member 31 and the second separate member 32 in the power cord holder 31d. Since no power cord holder 31d to hold the power cord 90 is required to be provided in a member other than the rear housing 30, the power cord 90 is capable of being arranged and held with a simple structure using the separable rear housing 30.

### Second Preferred Embodiment

A second preferred embodiment of the present invention will be described referring to FIGS. 6 to 10. Unlike the first preferred embodiment configured such that the signal processing board 41 and the power source board 42 are arranged in the inner sides (sides in the Y1 direction) of the first separate member 31 and the second separate member 32, respectively, the second preferred embodiment is configured such that a signal processing board 141 and a power source board 142 are both arranged in the inner side of the first separate member 31 as will be described below.

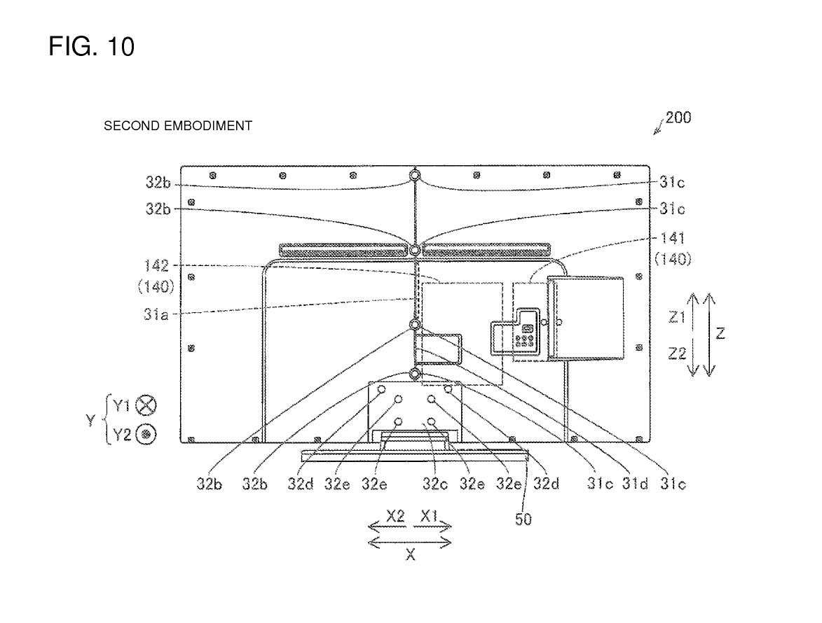

As illustrated in FIG. 10, the television device 200 according to the second preferred embodiment of the present invention includes a rear housing 130 which is configured to be separated into a first separate member 31 and a second separate member 132 preferably made of a resin material having lower fire-resistance than the first separate member 31 and a circuit board 140 including the signal processing board 141 and the power source board 142 arranged in the inner side (the side in the Y1 direction) of the first separate member 31. Note that, the same configuration as the first preferred embodiment is identified with the same reference signs and the description thereof is omitted. The television device 200 is an example of the “display device” according to a preferred embodiment of the present invention. The signal processing board 141 and the power source board 142 are examples of the “circuit board” according to a preferred embodiment of the present invention.

Now, the fire-resistance of the resin material will be explained. For example, the fire-resistance of resin materials is determined by fire-resistance grade is specified in UL94 standard. Specifically, UL94 standard determines the fire-resistance grades as, from the higher fire-resistance to the lower one, 5VA, 5VB, V-0, V-1, V-2, and HB.

According to a standard of safety such as UL 60950, a resin material having the fire-resistance of V-2 grade or higher is required for a member covering the circuit board 140 that generates heat.

The television device 200 of the second preferred embodiment is configured to include a partition with a wall panel 31a (see FIG. 6) between the first separate member 31 covering the circuit board 140 and the second separate member 132 so that only the first separate member 31 covers the circuit board 140 generating heat. Therefore, while the first separate member 31 preferably is made of a resin material having the fire-resistance grade of V-2 or higher, the second separate member 132 can be made of a resin material having the fire-resistance grade lower than V-2.

Other configurations of the second preferred embodiment is preferably the same or substantially the same as the first preferred embodiment.

The second preferred embodiment provides an effect as will be described below.

As described above, the second preferred embodiment is configured to have the rear housing 130 including the wall panel 31a extend inward (in the Y1 direction) toward the display module 10 from the area at or near one of the end portions of the first separate member 31 that is closer to the second separate member 132 (the side in the X2 direction) to significantly reduce or prevent bending and deformation of the rear housing 130, similarly to the first preferred embodiment.

In the second preferred embodiment as described above, the circuit board 140 is arranged in the inner side (the side in the Y1 direction) of the first separate member 31 but not in the inner side of the second separate member 132. The second separate member 132 is preferably made of a material having lower fire-resistance than the first separate member 31 in which inner side the circuit board 140 is arranged. While the first separate member 31 in which inner side the circuit board 140 generating heat is arranged preferably is made of a fire-resistance material (a resin material of grade V-2 or higher), the second separate member 132 in which inner side no circuit board 140 generating heat is arranged can be made of a material having lower fire-resistance than the first separate member 31 (a resin material of grade lower than V-2). This broadens the range of choice of materials of the first separate member 31 and the second separate member 132 constituting the rear housing 130.

Other effects and advantages of the second preferred embodiment preferably are preferably the same as the first preferred embodiment.

### Third Preferred Embodiment

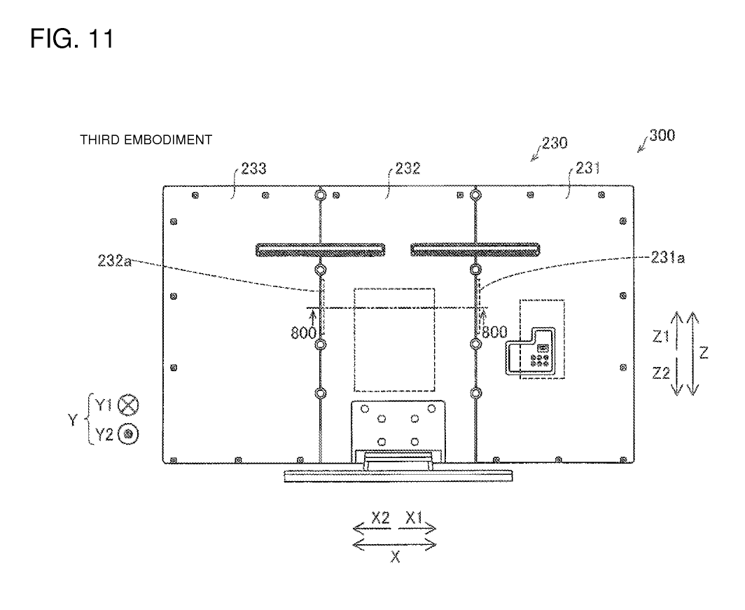

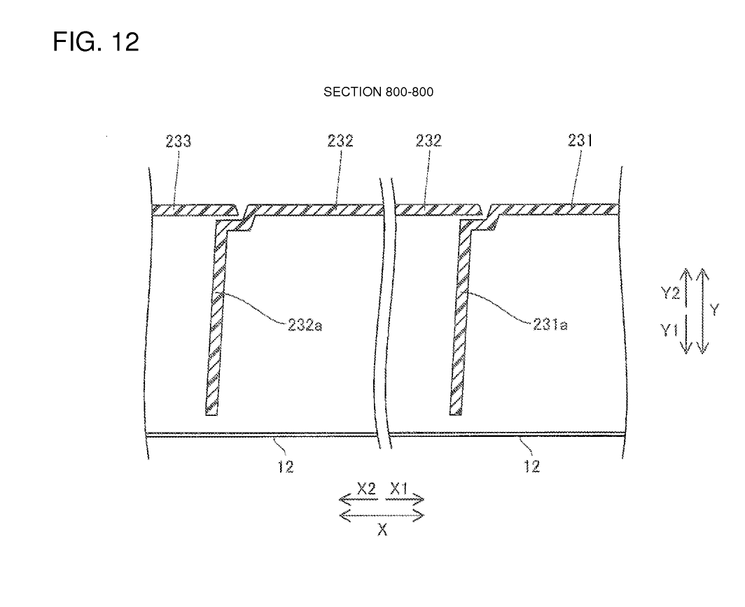

A third preferred embodiment of the present invention will be described referring to FIGS. 11 and 12. Unlike the first preferred embodiment which includes the rear housing 30 (130) separated into the first separate member 31 and the second separate member 32 (132), the third preferred embodiment is configured such that the rear housing 230 is separated into a first separate member 231, a second separate member 232, and a third separate member 233.

As illustrated in FIG. 11, a television device 300 according to the third preferred embodiment of the present invention includes the rear housing 230 separated into the first separate member 231, the second separate member 232, and the third separate member 233. The television device 300 further includes a circuit board 240 including a signal processing board 241 arranged in the inner side (the side in the Y1 direction) of the first separate member 231 and a power source board 242 arranged in the inner side of the second separate member 232. The same configuration as the first preferred embodiment is identified with the same reference signs and the description thereof is omitted. The television device 300 is an example of the “display device” according to a preferred embodiment of the present invention. The signal processing board 241 and the power source board 242 are examples of the “circuit board” according to a preferred embodiment of the present invention.

As illustrated in FIG. 12, the third preferred embodiment is configured such that the rear housing 230 is provided with a wall panel 231a extending inward from the area at or near one of the end portions of the first separate member 231 that is closer to the second separate member 232 (the side in the X2 direction) and the wall panel 232a extending inward from the area at or near one of the end portions of the second separate member 232 that is closer to the third separate member 233 (the side in the X2 direction).

The third preferred embodiment is configured such that the third separate member 233 of the rear housing 230 is preferably made of a resin material having lower fire-resistance than the resin materials of the first separate member 231 and the second separate member 232 in which inner side the circuit board 240 is arranged.

Other configurations of the third preferred embodiment are preferably the same as the first preferred embodiment.

The third preferred embodiment provides effects and advantages as will be described below.

As described above, the third preferred embodiment is configured to have the rear housing 230 including the wall panel 231a extending inward (in the Y1 direction) toward the display module 10 from one of that end portions of the first separate member 231 that is closer to the second separate member 232 (the side in the X2 direction) and the wall panel 232a extending inward toward the display module 10 from one of the end portions of the second separate member 232 that is closer to the third separate member 233 (the side in the X2 direction) to significantly reduce or prevent bending and deformation of the rear housing 230, similarly to the first preferred embodiment.

In the third preferred embodiment as described above, the circuit board 240 is arranged in the inner side (the side in the Y1 direction) of the first separate member 231 and the second separate member 232 but not in the inner side of the third separate member 233. Thus, similarly to the second preferred embodiment, while the first separate member 231 and the second separate member 232 in which inner side the circuit board 240 generating heat is arranged are preferably made of fire-resistance materials (resin materials of grade V-2 or higher), the third separate member 233 in which inner side no circuit board 240 generating heat is arranged can be made of a material having lower fire-resistance than the first separate member 231 or the second separate member 232 (resin material of grade lower than V-2). This broadens the range of choice of the materials of the first separate member 231, the second separate member 232, and the third separate member 233 constituting the rear housing 230.

Other effects and advantages of the third preferred embodiment are preferably the same as the first preferred embodiment.

The preferred embodiments and modifications thereof disclosed herein are only examples and are not limiting of the present invention. The scope of the present invention is determined by the claims and not by the preferred embodiments described above. All modifications within the meaning and range of equivalency of the claims fall within the scope of the present invention.

For example, the first preferred embodiment and the second preferred embodiment preferably are provided with the wall panel 31a only in the first separate member 31 and the third preferred embodiment are provided with the wall panel 231a in the first separate member 231 and the wall panel 232a in the second separate member 232, although the preferred embodiments of the present invention are not limited to such configurations. The wall panel preferably is provided in all the separate members of the rear housing in the preferred embodiments of the present invention. For example, the wall panel may be provided in the second separate member 32 (132) of the rear housing 30 (130) and in the third separate member 233 of the rear housing 230.

In the first preferred embodiment and the second preferred embodiment, the rear housing 30 (130) is separated into the first separate member 31 and the second separate member (132) and in the third preferred embodiment, the rear housing 230 is separated into the first separate member 231, the second separate member 232, and the third separate member 233, although the preferred embodiments of the present invention is not limited to such configurations. The rear housing may be separated into three or more separate members in the preferred embodiments of the present invention.

In the first preferred embodiments of the present invention, the wall panel 31a of the first separate member 31 extends inward (in the Y1 direction) from the internally overlapping portion 31f to the area at or near the rear frame 12, although the preferred embodiments of the present invention are not limited to such configuration. The wall panel may extend inward directly from one of end portions close to the second separate member of the first separate member without providing the internally overlapping portion in the first separate member of the rear housing in the preferred embodiments of the present invention.

The first preferred embodiment preferably includes one first engagement portion 31h in the first separate member 31 and one second engagement portion 32a in the second separate member 32, although the preferred embodiments of the present invention is not limited to such configuration. A plurality of first engagement portions and a plurality of second engagement portions corresponding to the plurality of first engagement portions may be provided in the preferred embodiments of the present invention.

The first preferred embodiment includes the wall panel 31a extending to the area at or near the rear frame 12, although the preferred embodiments of the present invention are not limited to such configuration. The wall panel may be configured to contact the rear frame or may not extend to an area at or near of the rear frame in the preferred embodiments of the present invention.

The first preferred embodiment includes the power cord holder 31d provided in the first separate member 31, although the preferred embodiments of the present invention are not limited to such configuration. The power cord holder preferably is provided in the second separate member in the preferred embodiments of the present invention.

In the second preferred embodiment, the first separate member 31 and the second separate member 132 are preferably made of different resin materials and in the third preferred embodiment, the third separate member 233 preferably is made of a resin material different from resin materials of the first separate member 231 and the second separate member 232, although the preferred embodiments of the present invention are not limited to such configuration. Separate members may be made of a same material in the preferred embodiments of the present invention.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A display device comprising:
a display module that displays images;
a front housing; and
a rear housing that holds and covers the display module between the front housing and to be separated into at least a first separate member and a second separate member; wherein
the rear housing includes a wall panel extending inward toward the display module from an area at or near at least one of an end portion of the first separate member that is closer to the second separate member or an end portion of the second separate member that is closer to the first separate member.

2. The display device according to claim 1, wherein the wall panel of the rear housing extends along a separation line defined by the at least one of the end portion of the first separate member that is closer to the second separate member and the end portion of the second separate member that is closer to the first separate member.

3. The display device according to claim 1, wherein
the first separate member of the rear housing includes an internally overlapping portion that overlaps with an inner side of the end portion of the second separate member that is closer to the first separate member; and
the wall panel of the rear housing extends inward toward the display module from the internally overlapping portion of the first separate member.

4. The display device according to claim 3, wherein
the first separate member of the rear housing includes a stepped portion that recesses inward such that the internally overlapping portion overlaps with an inner side of the end portion of the second separate member that is closer to the first separate member; and
the rear housing is positioned such that an outer surface of the first separate member and an outer surface of the second separate member are co-planar or approximately co-planar with each other when the internally overlapping portion of the first separate member and the end portion of the second separate member that is closer to the first separate member overlap with each other.

5. The display device according to claim 4, wherein the rear housing is positioned such that a side end surface of the end portion of the second separate member that is closer to the first separate member and a side surface of the stepped portion facing the side end surface are separated by a predetermined distance when the internally overlapping portion of the first separate member and the end portion of the second separate member that is closer to the first separate member overlap with each other.

6. The display device according to claim 1, wherein
the wall panel of the rear housing is provided in an area at or near the end portion of the first separate member that is closer to the second separate member;
the wall panel includes a first engagement portion projecting toward the second separate member; and
the second separate member of the rear housing includes a second engagement portion that engages with the first engagement portion so as to prevent the second separate member from rising against the first separate member.

7. The display device according to claim 1, wherein
the display module includes a display panel and a rear frame that supports the display panel; and
the wall panel of the rear housing extends to an area at or near the rear frame.

8. The display device according to claim 7, further comprising:
a circuit board arranged not in an inner side of one of the first separate member and the second separate member but in an inner side of another of the first separate member and the second separate member; wherein
the one of the first separate member and the second separate member of which inner side the circuit board is not arranged is made of a material having lower fire-resistance than a material of the other member of which inner side of the circuit board is arranged.

9. The display device according to claim 1, wherein
at least one of the first separate member and the second separate member is provided with a power cord holder that holds a power cord in an area at or near a separation line defined by the at least one of the end portion of the first separate member that is closer to the second separate member and the end portion of the second separate member that is closer to the first separate member; and
when the first separate member and the second separate member are assembled to form the rear housing, the first separate member and the second separate member hold the power cord in the power cord holder.

10. The display device according to claim 1, wherein the first separate member of the rear housing includes a plurality of bosses each including a threaded hole that engages with a screw member, a plurality of bosses each including a penetration hole that receives the screw member, a power cord holder that holds a power cord, and a base attaching portion that attaches a base.

11. The display device according to claim 10, wherein the base attaching portion extends toward the second separate member farther than a separation line defined by the at least one of the end portion of the first separate member that is closer to the second separate member and the end portion of the second separate member that is closer to the first separate member.

12. The display device according to claim 1, wherein the wall panel of the first separate member is integral with the first separate member so as to define a single unitary member.

13. The display device according to claim 4, wherein the wall panel of the first separate member, the stepped portion, and the internally overlapping portion are integral with the first separate member so as to define a single unitary member.

14. The display device according to claim 1, wherein the first separate member and the second separate member include first and second bosses including structures that are capable of being fitted together.

15. The display device according to claim 14, wherein the first boss has an L-shape cross section and the second boss has a U-shape cross section.

16. The display device according to claim 14, wherein the rear housing includes a gap between the first boss and the second boss.

17. The display device according to claim 1, further comprising a signal processing board and a power source board provided in inner sides of the first separate member and the second separate member, respectively.

18. The display device according to claim 1, further comprising a signal processing board and a power source board both provided in an inner side of the first separate member.

19. The display device according to claim 1, wherein the rear housing is separated into the first separate member, the second separate member, and a third separate member.

20. The display device according to claim 19, wherein the third separate member is made of a resin material having lower fire-resistance than that of the first separate member and the second separate member.
